(19) United States
(12) Patent Application Publication
(10) Pub. No.: US 2011/0056074 A1
(43) Pub. Date: Mar. 10, 2011

(54) APPARATUS AND METHOD FOR ELECTRONIC CIRCUIT MANUFACTURE

(75) Inventors: Kevyn Barry Jonas, Bristol (GB); Geoffrey McFarland, Wotton-under-Edge (GB)

(73) Assignee: RENISHAW PLC, WOTTON-UNDER-EDGE, GREAT BRITAIN (GB)

(21) Appl. No.: 12/918,951

(22) PCT Filed: Mar. 17, 2009
(86) PCT No.: PCT/GB09/00720

§ 371 Date: Aug. 23, 2010

Related U.S. Application Data
(60) Provisional application No. 61/064,673, filed on Mar. 19, 2008.

(30) Foreign Application Priority Data
Mar. 18, 2008 (GB) 0805021.3

(51) Int. Cl. H05K 3/00; B23P 19/00

(52) U.S. Cl. 29/829; 29/729

(57) ABSTRACT

An apparatus and method are described for use in the manufacture of non-planar circuit modules. The apparatus includes a holder for holding a non-planar circuit module, an activation source for activating one or more localised regions of a non-planar circuit module held by the holder, and positioning apparatus for providing relative movement between the activation source and a non-planar circuit module held by the holder. The relative movement between the activation source and a non-planar circuit module held by the holder includes translational movement along at least one axis and rotational movement about at least one axis. A parallel positioning machine may provide such relative movement.

The present invention relates to an apparatus and method for the production of electronic circuitry and in particular to an apparatus and method for providing components on non-planar circuit module substrates.

Circuit boards are found in the majority of commercially available electronic devices. Typically, a printed circuit board (PCB) is used to mechanically support and electrically connect electronic components using conductive pathways, or tracks, etched from copper sheets laminated onto a non-conductive substrate. A PCB populated with components is often called a printed circuit board assembly (PCBA).

Numerous production processes have been developed over the years for producing PCBAs. The vast majority of PCBs are made by bonding a layer of copper over an entire insulating (e.g. glass fibre or plastic) substrate. Copper is then selectively removed from the substrate to leave only the desired copper pathways using techniques such as screen printing, photoengraving or PCB milling. After the PCB has been produced, electronic components are attached to form the PCBA. These component may be attached to solder pads provided on the outer surface of the PCB (surface mounting) and/or component leads may be inserted into vias formed in the PCB (through-hole mounting). A molten metal solder is then used to fix the components to the PCB.

At present, the manufacture of the majority of PCBAs is performed using a surface mounting technique that includes a reflow soldering stage. In such a technique, the solder pads of the board are plated with a solder paste before component placement. An automated “pick and place” machine is then used to locate the components on the appropriate pads of the board. The board is then placed in a reflow soldering oven that typically comprises multiple stages for gradually heating (e.g. using a heated gas or infrared radiation) the whole board until a temperature is reached at which the solder paste melts or reflows. The board is then slowly cooled whereupon the molten solder solidifies and holds the components in place.

Known solder reflow based techniques for producing PCBAs have a number of disadvantages. For example, placing the circuit board in a reflow oven can introduce thermal stresses and may also cause unwanted heating of thermally sensitive electronic components. Although the gradual heating process used by typical reflow soldering ovens can reduce some heat related problems, it can greatly increase the time taken to produce each PCBA. In addition, methods using solder reflow ovens become more complex when attaching components to both sides of a PCB. In particular, after the solder paste has melted (but before it re-solidifies) it provides only a very weak bond between the component and the board. Any components placed on the underside of the board will thus simply fall off when the board is placed in the reflow oven. Surface mounting techniques have previously been extended to mounting components on both sides of a board, but this requires an additional step of also gluing components to the underside of the board to hold them in place during the solder reflow step.

To make more compact circuits assemblies, for example to fit inside the casing of a small device, it also known to use the above described solder reflow based techniques to manufacture flexible or bendable circuits. A flexible PCB is thus held flat during the component placement and reflow soldering steps and is subsequently bent into the required shape. However, the amount of substrate bending that can occur without damaging the electrical links between the components and the flexible board is limited. Despite these drawbacks, flexible circuit boards manufactured using solder reflow processes are widely considered to be the only practical way of producing more compact devices using automated production techniques.

It has also been proposed previously to reduce the size of electronic devices by forming electronic circuitry on the internal surfaces of device casings or the like.

However, the irregular (non-flat) shape of such surfaces requires components to be attached by hand using a soldering iron because automated reflow oven based techniques can not be easily adapted to manufacture such devices. Forming integral circuitry in this manner has thus only been used for niche, high cost, applications due to the expense associated with manual manufacturing techniques.

According to a first aspect of the invention, apparatus for use in the manufacture of a non-planar circuit module comprises; a holder for holding a non-planar circuit module, an activation source for activating one or more localised regions of a non-planar circuit module held by the holder, and positioning apparatus for providing relative movement between the activation source and a non-planar circuit module held by the holder, wherein the relative movement between the activation source and a non-planar circuit module held by the holder comprises translational movement along at least one axis and rotational movement about at least one axis.

The present invention thus provides apparatus for manufacturing non-planar circuit modules. The apparatus includes a holder for holding a non-planar circuit module and an activation source, such as a heater or a radiation source. In use, the positioning apparatus provides relative motion between the activation source and the non-planar circuit module. In particular, the positioning apparatus controls at least one of the translational degrees of freedom and at least one of the rotational degrees of freedom between the activation source and a non-planar substrate held by the holder. As described in more detail below, such relative motion may be provided by moving the activation source using a positioning device and/or by using the holder to move the non-planar circuit module.

In use, the activation source is moved in to an operative position relative to the non-planar circuit module and arranged to activate selected regions of material on the non-planar circuit module. As explained in more detail below, the activation source activates or affects selected regions of the non-planar circuit module to leave behind a structure that permits electronic action. The activation source may thus melt regions of solder paste, cure an adhesive or ablate material etc. In other words, the activation source modifies properties of material forming the non-planar circuit module to implement the necessary electronic function. It should also be noted that activating material using the activation source may provide or block an effect. For example, a so-called positive process may be used in which material is activated to provide a certain function (e.g. fluid is activated to form a conductive track, provide a solder connection etc). Alternatively, a negative process may be employed in which any activated material does not provide a function; e.g. an activated region of the non-planar circuit module may become electrically insulating or more readily removable during a subsequent process step. It should be noted that the activation provided by the activation source may form one or more of several process steps. For example, activation may be followed by the application of a metal coating; the deposition of the metal coating being determined by the prior surface activation.

Providing translational and rotational motion in accordance with the present invention allows the position and orientation of the activation source relative to the non-planar circuit module to be controlled. In particular, this allows desired regions of the non-planar circuit module to be activated without activating surrounding areas. For example, if the activation source comprises a directional (non-contact) radiation source for melting solder paste, the apparatus of the present invention can be seen to allow the radiation output by that source to be directed to regions of solder paste to be melted without melting solder paste coated on other areas of the circuit module.

The present invention thus allows regions on a non-planar circuit module to be activated (e.g. melted or cured) in series. This is particularly advantageous when the activation source is being used to activate a material (e.g. a solder paste) that is being used to attach a component to a non-planar substrate of the non-planar circuit module. Consider, for example, a non-planar substrate having a plurality of component mounting faces each having pads coated in solder paste. The viscosity of the solder paste may be sufficient to hold some of the (lighter) components in place at room temperature, but melting all the solder paste simultaneously (e.g. using a solder reflow oven) may cause some of the components to move or drop off their respective mounting surfaces.

The present invention allows the solder paste associated with each component or a subset of components to be melted in turn. This would mean, for the above soldering example, the non-planar circuit module could be re-orientated between each melting step. For example, it could be ensured that each mounting surface of the non-planar substrate is approximately horizontal when solder paste located thereon is being heated to ensure the components remain in place during the soldering process. Alternatively, a pick-up device of the type described below that may be used to place components onto the mounting surface may be used to hold each component in place until the solder joint is formed. The present invention thus allows, unlike known prior art techniques, the automated manufacture of non-planar circuit modules thereby providing significant cost savings compared to manual production techniques.

The activation source advantageously comprises a heat source for heating one or more localised regions of a non-planar circuit module held by the holder and/or a directional radiation source for directing radiation to one or more localised regions of a non-planar circuit module held by the holder. In other words, the activation source may comprise a source of heat and/or radiation. The activation source is preferably directional or focussed so that localised regions or areas of the non-planar circuit module are activated without affecting surrounding areas. The activation source may be a contact heat source, such as a heated tip, that is brought into physical contact with the fluid and/or the substrate. Advantageously, the activation source is a (non-contact) radiation source such as an ultraviolet (UV) light source, a laser, an acoustic source or a microwave radiation source.

Advantageously, the activation source comprises an open ended microwave cavity; e.g. a frequency agile open ended microwave cavity. Advantageously, the activation source is a Frequency Agile Microwave Oven Bonding System (FAMOBS) of the type described in K. I. Sinclair et al, Proc. IEEE Electronics System Integration Technology Conference 2006, Vol. 2, pp 1149-1157 and T. Tilford et al, 41^{st} Annual Microwave Symposium Proceedings of the International Microwave Power Institute, Aug. 1-3, 2007, the contents of which are incorporated herein by reference. The use of a FAMOBS heat source is particularly advantageous as it can be tuned so as to heat a fluid through a component (e.g. to provide sub-surface curing) thereby reducing the amount of machine movement that is required during any place and cure operations.

Advantageously, the holder is arranged to hold (or is holding), a non-planar circuit module that comprises a non-planar substrate. In particular, the non-planar substrate may be mountable to or on the holder. Such a holder may be a general purpose holder or it may be fabricated to hold a specific type or kind of non-planar substrate as necessary. The term non-planar substrate as used herein encompasses any substrate that is not flat but has some kind of three dimensional shape; the term thus includes regular 3D shapes (cubes, cuboids etc), objects having one or more curved surfaces, freeform surfaces and objects having a plurality of faces or facets that are located in different planes or have different surface normals. Conveniently, the non-planar substrate held by the holder comprises a substrate having at least two or at least three component mounting surfaces. Such component mounting surfaces are conveniently located in different planes (i.e. have different surface normals). The non-planar substrate may conveniently comprise at least one curved component mounting surface. Examples of a non-planar substrate may thus include substrate(s) formed from a curved or bent sheet of material. The moulded plastic casings or housings of electronic devices are thus also types of non-planar substrate. The non-planar substrate may also be foldable or already folded into a required shape.

The type of activation source employed is conveniently selected to activate a selected material or materials of the non-planar circuit module. Such activation may also include burning or ablating material; such material removal may be used as part of a disassembly or rework process. It should be noted that the non-planar circuit module may comprise a non-planar circuit assembly in which discrete components are attached to a non-planar substrate or a non-planar circuit in which electronic components are formed on a non-planar substrate by fluid deposition or the like. In a preferred embodiment, the non-planar circuit module held by the holder further comprises a fluid (e.g. an adhesive or solder paste deposited on the non-planar substrate) and the activation source can activate (e.g. cure or melt) the deposited fluid.

As outlined above, positioning apparatus of the present invention provides motion between the activation source and a non-planar circuit module held by the holder. This motion may be provided by moving (relative to a fixed or ground point) the activation source and/or by moving (e.g. tilting) the non-planar circuit module.

Advantageously, the positioning apparatus comprises a positioning device for moving the activation source. The positioning device may translate and/or rotate the activation source as required. In other words, the positioning device may control any one or more of the six degree of freedom of movement of the activation source. Advantageously, the positioning device provides translational movement of the activation source along one or more axes. For example, the positioning device may be operable to translate the activation source along one (e.g. X) axis, along two mutually orthogonal (e.g. X, Y) axes or along three mutually orthogonal (e.g. X, Y, Z) axes. The positioning device may also provide rotational movement of the activation source about one or more axes. For example, the positioning device may be arranged to rotate the activation source about one, two or three axes.

The positioning device may comprise any type of robot or positioning machine. The positioning machine may have a fixed base and a moveable mount to which the activation source is mounted. The positioning device may comprise a positioning machine having a so-called Cartesian (non-parallel) configuration in which a movable mount is supported for movement relative to a base with three translational degrees of freedom by means of three serially mounted (i.e. one on top of another), mutually orthogonal linear guideways. Advantageously, the positioning device comprises a non-Cartesian or parallel positioning machine in which the moveable mount is attached to the base by plurality of extendable legs.

The parallel positioning machine may comprise a hexapod or Stewart platform having six extendable legs linking the base to the moveable mount and thereby controlling all six degrees of freedom between the base and the moveable mount. Conveniently, the parallel positioning machine includes a constraining mechanism that constrains at least one of the degrees of freedom between the base and the moveable mount. In a preferred embodiment, a parallel positioning machine is provided in which all rotational degrees of freedom between the base and the moveable mount are constrained. In such an arrangement, three extendable legs provide control over the relative position of the base and moveable mount and a plurality of fixed length legs prevent any rotation. Examples of such a constrained parallel positioning machine are described in EP1612506 and U.S. Pat. No. 7,241,070, the contents of which are incorporated herein by reference. Parallel positioning machines are preferred, but are by no means essential, as they have various advantages in terms of speed of motion, cost of construction and access compared with serial positioning machines. The positioning device may also comprise both parallel and non-parallel positioning machines.

It should be noted that the activation source may form part of an activation system that includes other components (e.g. a power supply, controller etc). In such an example, the activation source alone may be moved by the positioning device. For example, the positioning device may move an activation source that comprises the distal end of an optical fibre. In such an example, the proximal end of the optical fibre may be coupled to a stationary laser. Alternatively, the activation source may comprise a heatable tip that is coupled to a stationary electrical power control system via an electrical cable. In other words, the positioning device may be arranged to only move around the part of the activation system that is heated or emits radiation.

The non-planar circuit module may also be moved about in space. The holder thus advantageously forms part of the positioning apparatus. In other words, the holder may permit the absolute orientation of the substrate (i.e. the orientation of the substrate relative to ground) to be altered. Conveniently, the holder comprises a tilting mechanism that enables a non-planar circuit module held by the holder to be tilted about at least one axis. For example, a table top on which a non-planar substrate can be held may be tilted away from the horizontal. Advantageously, the tilting mechanism allows the non-planar circuit module to be tilted about two or more axes. The non-planar circuit module may be tiltable from the horizontal by more than 10°, by more than 45° or by more than 90°. The holder may also provide additional movement of the non-planar circuit module. For example, the holder may also allow the non-planar circuit module to be translated along one or more axes (e.g. moved “up and down”) or rotated about a vertical axis.

Advantageously, the holder comprises a tilting table having a table base and a tiltable table top, wherein a non-planar circuit module can be releaseably retained on the tiltable table top. The non-planar circuit module may be held on the table top in a variety of ways; for example, clips, clamps, screws, a vacuum chuck, a vacuum bed or other retaining means may be provided. Advantageously, the retaining means is automated so that the non-planar circuit module can be held and released as necessary under control of the apparatus.

Advantageously, the apparatus comprises a fluid dispenser for dispensing fluid on to a non-planar circuit module held by the holder. It should also be noted that, herein, the term fluid takes the meaning well known to those skilled in the art of being any non-solid material that flows or is composed of particles that can move about with freedom. The term fluid thus includes pastes (e.g. solder paste), colloid suspensions, gels, liquids, solvents and inks etc.

Advantageously, the positioning apparatus is arranged to move the fluid dispenser so as to bring it in to an operable position relative to a non-planar substrate of the circuit module whereupon fluid can be deposited on the selected area or areas of the non-planar substrate. In a preferred embodiment, the fluid dispenser and activation source may both be mounted so as to move with a moveable mount or arm of a positioning device as described above.

If a fluid dispenser is moved by the positioning apparatus, it may comprise the nozzle(s) or outlet(s) through which fluid is expelled. The fluid dispenser may form a part of a fluid dispensing system that also includes further parts (e.g. a fluid reservoir, pump, supply tubes etc). These additional parts of the fluid dispensing system are not necessarily mounted to or moved by the positioning apparatus. For example, a positioning device may move a fluid dispensing nozzle, the nozzle being connected by a length of flexible tubing to a pump and reservoir located on a stationary part of the apparatus.

In a preferred embodiment, the positioning apparatus comprises a positioning device for moving the fluid dispenser and the holder comprises a tilting mechanism for altering the absolute orientation of the non-planar substrate of the non-planar circuit module. In this manner, the apparatus controls the position and orientation of the non-planar substrate relative to the fluid dispenser and also controls the absolute orientation of the substrate. This has the advantage of providing control over the flow of any fluid, especially lower viscosity fluid, dispensed on to a non-planar substrate. For example, appropriately orientating a non-planar substrate to ensure that a localised region is at least approximately horizontal prevents any unwanted flowing of the fluid deposited on that region. Furthermore, the ability to control absolute substrate orientation is also advantageous if components are attached to the non-planar substrate using the dispensed fluid. For example, appropriate orientation of the non-planar substrate can ensure that components do not shift in position (e.g. due to gravity) after being placed on solder or adhesive deposited on the non-planar substrate but prior to that adhesive or solder paste being cured by the activation source. Tilting the substrate in addition to moving the fluid dispensing device can also provide improved access to certain regions or features of the substrate compared with moving the fluid dispensing device alone.

Advantageously, the apparatus comprises a component pick-up device such as a vacuum nozzle or other gripping means. The component pick-up device may be arranged to pick up components and place such components on a non-planar circuit module held by the holder. It should be noted that placing a component as described herein may involve the component pick-up device bringing the component into direct contact with the non-planar circuit module or projecting (e.g. firing/launching) the component across a gap so as to land on the non-planar circuit module in the required position and orientation. Conveniently, an electrical or electro-optic component is picked up by the pick-up device. The component pick-up device is preferably moved by the positioning apparatus. Advantageously, the pick-up device allows the component to be rotated to provide the required alignment between the component and the non-planar circuit module; e.g. the pick-up device may be rotated by the positioning apparatus to appropriately align the component relative to the non-planar circuit module.

Advantageously, the fluid dispenser, activation source and component pick-up device as described above may all be mounted so as to move with a moveable mount of the positioning device. As outlined in more detail below, such apparatus may be used to deposit adhesive on the non-planar circuit module, place a component in the adhesive and cure the adhesive to fix the component in place.

Preferably, the apparatus is operated under the control of a computer. Advantageously, a position feedback system is provided for sensing the position of the activation source relative to a non-planar circuit module held by the holder. The position feedback system may comprise position encoders or the like that form part of the positioning apparatus and thus provide appropriate position and orientation information. The position feedback system may also include an image or video recognition system (e.g. comprising one or a plurality of video cameras) for determining the position and/or orientation of the non-planar circuit module relative to the activation source. In this manner, a feedback control loop may be provided to ensure the required area of the substrate is activated. Such an image recognition system may also be used during any fluid deposition and component placement.

The activation source may, in use, be permanently attached to a part of the positioning apparatus. For example, the activation source may be bolted or welded to a moveable platform of a positioning device. Similarly, any fluid dispenser and/or component pick-up device may, in use, be permanently attached to such a positioning device. Advantageously, the activation source is, during use, releasably attachable to the positioning apparatus. For example, a releasable connector (e.g. a magnetised kinematic mount) or clamp may be used to attach the activation source to the positioning device. In this manner, the activation source may be attached to the positioning apparatus only when it is required. Conveniently, the releasable connector allows the activation source to be automatically detached from the positioning device (e.g. without the need for a technician to remove a bolt) when an appropriate control instruction is issued by the computer control system. Inbetween using the activation source, the positioning device may carry other devices, such as a fluid dispenser or a pick-up device. A rack may be conveniently provided for storing the activation source and any fluid dispenser or pick-up device when not in use.

According to a second aspect of the invention, there is provided apparatus for use in the manufacture of a circuit module, the apparatus comprising; a holder for holding a circuit module, a heat source for heating one or more localised regions of material on the circuit module, and positioning apparatus for providing relative movement between the heat source and a circuit module held by the holder, wherein the relative movement between the heat source and a circuit module held by the holder comprises translational movement along at least one axis and rotational movement about at least one axis.

In this second aspect, the present invention can be seen to offer advantages when it is necessary to heat circuit modules (e.g. to melt solder) that have thermally sensitive regions. In particular, it allows automated manufacture of planar or non-planar circuit modules without having to bake the entire substrate on which the circuit module is formed in a solder reflow oven for prolonged periods of time.

According to a third aspect of the invention, a method of manufacturing a non-planar circuit module is provided, the method comprising the steps of; (i) taking a non-planar circuit module; and (ii) bringing an activation source in to an operative position relative to the non-planar circuit module and using the activation source to activate one or more localised regions of the non-planar circuit module, wherein step (ii) comprises the step of using positioning apparatus to move the activation source relative to the non-planar circuit module, wherein the relative movement between the activation source and a non-planar circuit module held by the holder comprises translational movement along at least one axis and rotational movement about at least one axis. As outlined above, such a method allows the automated manufacture of non-planar circuit modules. In particular, it permits circuitry to be formed on the surfaces of the plastic casing of electronic devices.

The motion between the substrate and activation source may be provided by the positioning apparatus in any suitable manner. Advantageously, step (ii) comprises the step of moving the activation source and/or the step of tilting the non-planar circuit module.

Conveniently, step (i) comprises the step of taking a non-planar circuit module comprising a non-planar substrate (e.g. the plastic casing of a device) having a fluid deposited thereon. The fluid advantageously comprises solder paste. Step (i) may also comprise the step of using a fluid dispenser to dispense a fluid on to the non-planar substrate. Advantageously, step (ii) comprises using the activation source to melt the solder paste.

Advantageously, step (i) comprises the step of taking a non-planar circuit module comprising a substrate having at least one electrical component (e.g. a silicon chip, optical detector etc) located thereon. The electrical component may be located in a fluid (e.g. solder paste) provided on the non-planar substrate. Advantageously, the activation source used in step (ii) comprises a microwave radiation source. Preferably, the activation source provides only localised action (e.g. localised heating). In a preferred embodiment, the microwave radiation source is a FAMOBS device thereby allowing heating of solder paste or the like through components located on the surface of the non-planar substrate.

According to a further aspect, the invention provides a method of manufacturing a circuit module, the method comprising the steps of; (i) taking a circuit module; and (ii) bringing heat source in to an operative position relative to the circuit module and using the heat source to heat one or more localised regions of the circuit module, wherein step (ii) comprises the step of using positioning apparatus to move the heat source relative to the circuit module, wherein the relative movement between the heat source and a circuit module held by the holder comprises translational movement along at least one axis and rotational movement about at least one axis.

The invention will now be described, by way of example only, with reference to the accompanying drawings in which;

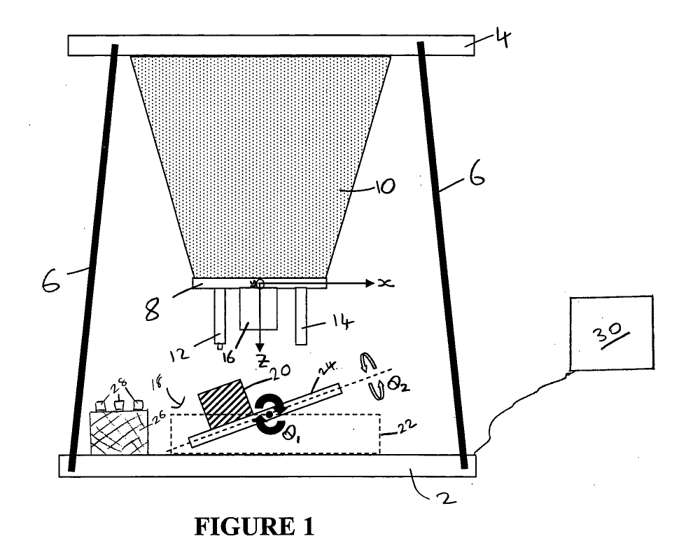

FIG. 1 illustrates an embodiment of the apparatus of the present invention,

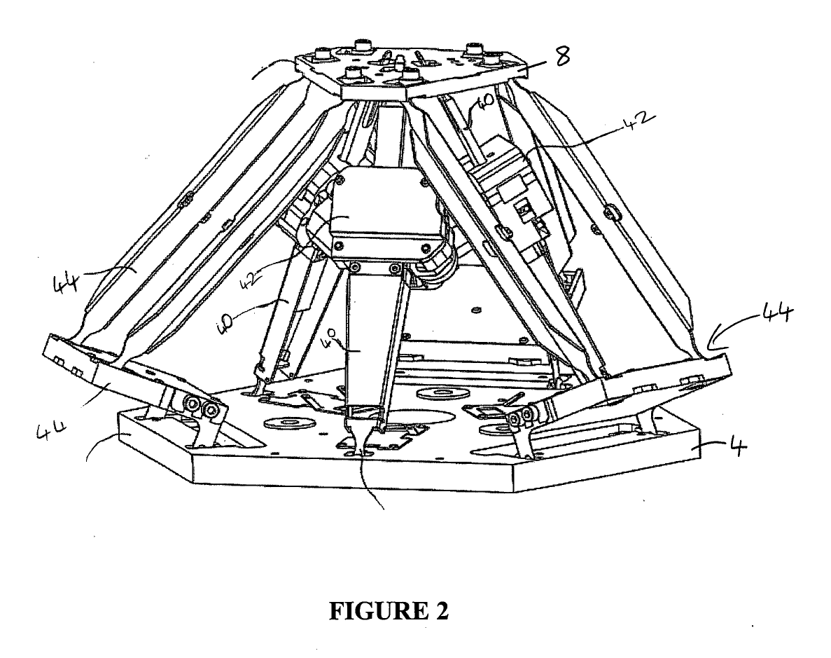

FIG. 2 shows the parallel positioning device of the apparatus of FIG. 1 in more detail,

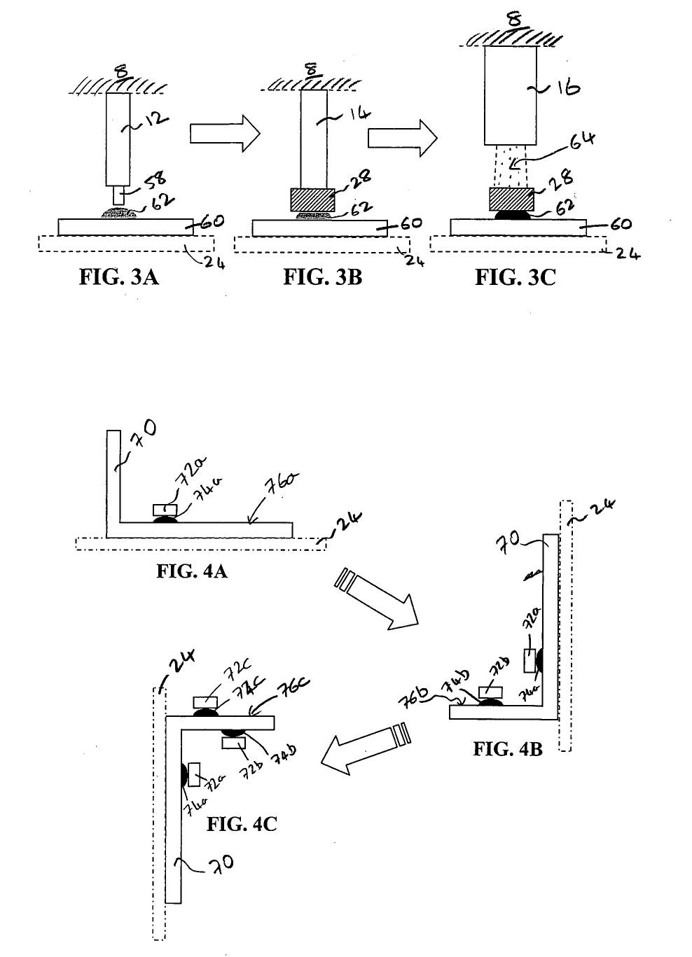

FIGS. 3a-3c illustrates a technique for attaching components to a substrate using apparatus of the type shown in FIGS. 1 and 2,

FIGS. 4a-4c show component placement on an L-shaped substrate using apparatus of the type shown in FIGS. 1 and 2,

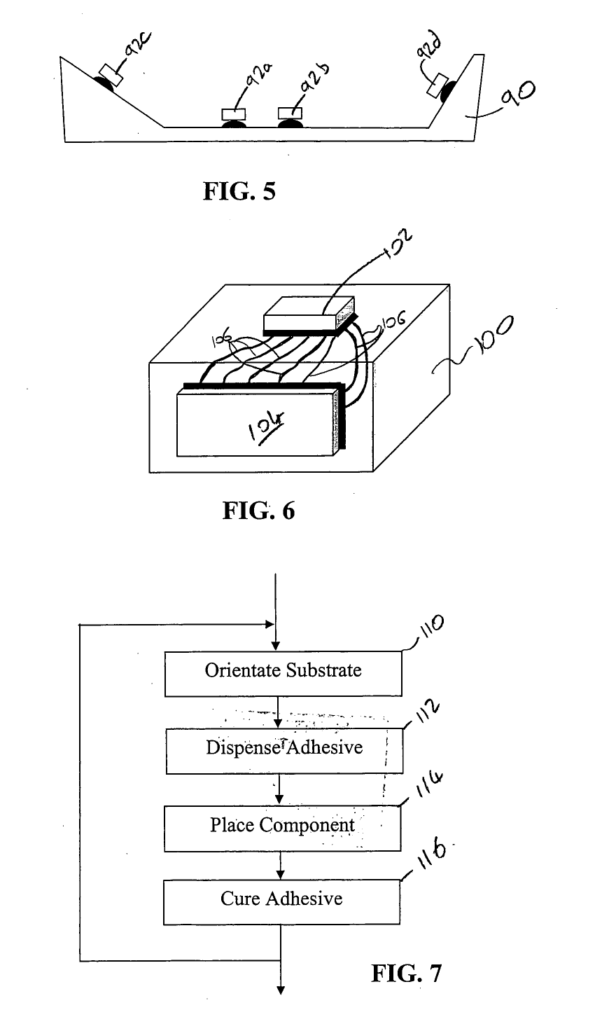

FIG. 5 shows component placement on an U-shaped substrate using apparatus of the type shown in FIGS. 1 and 2

FIG. 6 shows component placement on an cuboidal substrate using apparatus of the type shown in FIGS. 1 and 2, and

FIG. 7 is a flow diagram outlining the steps of a method according to the present invention.

Referring to FIG. 1, apparatus of the present invention is illustrated.

The apparatus comprises a bed 2 fixed to an upper or base platform 4 by a plurality of support struts 6. The support struts 6 are sufficiently rigid to ensure the base platform 4 is held in a fixed position relative to the bed 2. The base platform 4 is also attached to a moveable platform 8 by a constrained parallel kinematic positioning mechanism 10. For clarity, details concerning the parallel kinematic positioning mechanism 10 are omitted from FIG. 1 and the mechanism is shown in detail in FIG. 2. The base platform 4, moveable platform 8 and parallel kinematic positioning mechanism 10 thus form a constrained parallel positioning machine that controls translational movement of the moveable platform 8 along three axes (X,Y,Z). The moveable platform 8 has a fluid dispensing device 12, a pick-up device 14 (e.g. a vacuum based pick-up device) and a FAMOBS device 16 mounted thereon. The fluid dispensing device 12 is connected to a remote fluid pump and reservoir via a fluid supply tube (not shown). In this example, the fluid dispensing device 12 is arranged to dispense a conductive adhesive paste but it should be noted that it may be used to dispense any type of fluid.

The moveable platform 8 shown FIG. 1 has the fluid dispensing device 12, the pick-up device 14 (e.g. a vacuum based pick-up device) and the FAMOBS device 16 all mounted thereon. This is, however, not essential. It would also be possible for the moveably platform 8 to include a mount for receiving any one of the fluid dispensing device 12, the pick-up device 14 (e.g. a vacuum based pick-up device) and the FAMOBS device 16 at any one time. In other words, the appropriate device could be mounted to the moveable platform 8 as and when required; the remaining devices could then be stored in a rack or placed in a storage area until they are needed.

Also mounted to the bed 2 of the apparatus is a holder 18 for holding a substrate 20. The holder 18 comprises a table base 22 and a table top 24 that can be tilted relative to the table base 22 about two orthogonal axes of rotation (θ₁ and θ₂). Such rotary movement may be provided by two serially mounted rotational stages. The table top 24 also comprises a clamp (not shown) for holding a substrate 20 placed thereon. The holder 18 thus provides a tilting mechanism that allows the absolute orientation of the substrate (i.e. the substrate orientation relative to the ground or, more importantly, relative to gravity) to be set. A component storage area 26 is also provided on the bed 2 for storing various components 28 prior to use.

A computer 30 is provided for controlling operation of the apparatus. In particular, the computer 30 controls motion of the moveable platform 8, the orientation of the substrate as defined by the holder 18, the dispensing of fluid from the fluid dispensing nozzle 12, operation of the pick-up device 14 and activation of the FAMOBS device 16. One or more video cameras (not shown) may also be provided that feed images back to the computer 30 that give information about the position of the apparatus relative to the substrate 20. Methods of using such apparatus are described in detail below.

Referring to FIG. 2, the constrained parallel positioning machine used in the apparatus of FIG. 1 will be described in more detail; noting that the illustration of the constrained parallel positioning machine given in FIG. 2 is inverted (i.e. upside down) compared with the view of FIG. 1.

The constrained parallel positioning machine comprises a base platform 4 that is mounted to a moveable platform or stage 8 by a plurality of struts. In particular, the base and moveable platforms 4 and 8 are linked by three powered telescopic struts 40, the ends of which are connected to the platforms by pivot joints. Each powered telescopic strut 40 has a motor 42 to increase or decrease its length and a position encoder (contained within the motor housing and therefore not visible in FIG. 2) to measure its length. Three anti-rotational devices 44 are also provided to constrain the three rotational degrees of freedom between the base platform 4 and the moveable platforms 8; the anti-rotational devices are passive and comprise no motor or other type of actuator. Extension of the powered telescopic struts 40 of the machine thus provides only translational (not rotational) movement between the base platform 4 and the moveable platforms 8. In other words, the moveable platform 8 can be translated in space relative to the fixed based platform 4 and such translation may be described in terms of movement along X, Y and Z axes.

Although the apparatus shown in FIGS. 1 and 2 comprises a constrained parallel positioning machine, it should be remembered that any type of positioning machine could be used. The positioning machine could include a serial or parallel mechanism as described above. The constrained parallel positioning mechanism and the holder 18 together provide positioning apparatus for moving the substrate relative to the moveable platform 8.

Referring to FIGS. 3a to 3c, the attachment of a component to a substrate using apparatus of the type described with reference to FIGS. 1 and 2 is illustrated.

FIG. 3a illustrates a first step in the process in which a nozzle 58 of the fluid dispensing device 12 is brought in to a fluid dispensing position relative to a substrate 60 mounted on the table top 24 of the holder 18. The necessary motion of the fluid dispensing device 12 is provided by movement of the moveable stage 8 of the apparatus. The required pattern of conductive adhesive 62 is then deposited on the substrate. This first step may, optionally, include monitoring the position of the nozzle 58 relative to the substrate 60 (e.g. using a video camera based image recognition system) to ensure the required pattern of adhesive is provided. Although only a single region or drop of adhesive is shown in FIG. 3a for clarity, it should be noted that a more complex adhesive pattern (e.g. corresponding to desired points of electrical connection with an electronic chip etc) may be laid down by the fluid dispensing device 12. Once the required pattern of adhesive has been deposited, the fluid dispensing device 12 is withdrawn from the substrate.

FIG. 3b illustrates a second step in the process in which a component 28 that has been picked up from the component storage area 26 by the pick-up device 14 is placed on the conductive adhesive 62. Again, motion of the pick-up device 14 is provided by movement of the moveable stage 8 of the apparatus. This second step may, optionally, include an active alignment step in which the orientation and position of the component 28 is monitored (e.g. using a video camera based image recognition system) thereby ensuring accurate placement. Once placed, the pick-up device 14 releases the component 28 and is withdrawn thus leaving the component 28 loosely attached to the substrate 60 via the uncured adhesive.

FIG. 3b illustrates a third step in which the moveable stage 8 moves the FAMOBS device 16 into proximity with the substrate 60. This third step may, optionally, include monitoring the position of the FAMOBS device 16 relative to the substrate 60 (e.g. using a video camera based image recognition system). As outlined above, a FAMOBS device emits microwave radiation of varying frequency and can be arranged to cause heating in certain materials (e.g. an adhesive or solder paste) whilst causing no significant heating in other materials (e.g. semiconductor materials used to form electronic components). It is thus possible, using a FAMOBS device, to cure an adhesive by directing the emitted microwave radiation onto that adhesive through a component. The FAMOBS device 16 is thus orientated by the moveable stage 8 so that it directs microwave radiation 64 into the conductive adhesive 62 through the component 28. The adhesive is thus cured without any damage to the component 28 and without having to provide a direct line of sight between the FAMOBS device 16 and the conductive adhesive 62. Once the conductive adhesive 62 is cured, the FAMOBS device 16 is withdrawn and the component 28 is securely attached to the substrate.

The above described apparatus may be used to attach components to planar substrates, such as a printed circuit board (PCB), but is particularly advantageous when using non-planar substrates. In particular, the above described apparatus facilitates the attachment of components to non-planar substrates thereby allowing three dimensional or non-planar circuit module to be formed.

Referring to FIGS. 4a-4c, a method is outlined for attaching components 72a, 72b and 72c to three mounting faces 76a, 76b and 76c of an L-shaped (non-planar) substrate 70 using the above described apparatus.

FIG. 4a shows an L-shaped substrate 70 retained on the tiltable table top 24 of the holder 18 with the tiltable table top 24 placed in a first orientation. The first orientation of the tiltable table top 24 is selected so that first mounting face 76a is substantially horizontal. A first electronic component 72a is mounted to the first mounting face 76a by conductive adhesive 74a using the steps described above with reference to FIG. 3.

At this point is should also be noted that the orientation of the mounting face need not be accurately horizontal. A certain amount of tilt of the surface away from horizontal is typically acceptable and the amount of tilt will depend on various factors, such as the viscosity of the uncured adhesive and the weight of the component.

After the first electronic component 72a has been attached to the first mounting face 76a, the tiltable table top 24 is moved into a second orientation as shown in FIG. 4b in which the second mounting face 76b is substantially horizontal. A second electronic component 72b is mounted to the second mounting face 76b by conductive adhesive 74b using the steps described above with reference to FIG. 3.

After the second electronic component 72b has been attached to the second mounting face 76b, the tiltable table top 24 is moved into a third orientation as shown in FIG. 4c in which the third mounting face 76c is substantially horizontal. A third electronic component 72c is mounted to the third mounting face 76c by conductive adhesive 74c, again using the steps described above with reference to FIG. 3.

This process may be continued until all the required components have been mounted to the L-shaped substrate 70 thereby forming the required circuit module. It should be noted that although the attachment of a single component to each mounting face is described, any number of components could be attached to each mounting face. Similarly, components could be attached to further faces of the L-shaped substrate 70 if required. An analogous process could also be used for attaching components to a continuously varying surface (e.g. a curved substrate); e.g. a substrate orientation could be selected that allows a subset of the components to be attached to part of the substrate before re-orientating the substrate. Furthermore, tilting about two axes (instead of the one axes shown in FIG. 4) could be implemented when using substrates having a more complex shape.

The process illustrated in FIG. 4 has been found to be particularly advantageous for forming three-dimensional electronic circuit modules from non-planar substrates that can form part of the casing of an electronic device.

Referring to FIG. 5, a portion of plastic casing 90 of an electronic device is shown. The plastic casing 90 has three internal mounting surfaces 92a-92c onto which four electronic components 92a-92d (e.g. electronic chips or other components) are mounted. The electronic components 92a-92d have been attached to each mounting surfaces 92a-92c in turn in the manner described with reference to FIG. 4. In particular, the plastic casing 90 would have orientated during fabrication so that each mounting surface was, in turn, held substantially horizontal for component attachment thereto. Various conductive tracks (not shown) can also be deposited on the plastic casing 90 to interconnect the various electronic components; these may be formed integrally with the casing or deposited using the fluid dispensing device 12 of the apparatus.

It can thus be seen that the present invention permits an electronic circuit to be formed on the various internal surfaces of the plastic casing 90. Such non-planar circuit modules have been proposed previously and provide various advantages (e.g. robustness and compactness) over traditional devices that are formed from planar or flexible electronic circuit boards located within a casing. Non-planar circuit modules are not, however, widely used at present because of the necessity to attach the various components to the substrate by hand. The apparatus described herein offers, for the first time, the ability to form such non-planar circuit modules using a totally automated assembly and attachment process. In other words, the present invention permits the fabrication of non-planar circuit modules to be automated thereby greatly reducing the cost of fabricating such circuit modules.

Referring to FIG. 6, a further non-planar substrate in the form of a cuboid 100 is illustrated. Components 102 and 104 may be attached to faces of the cuboid 100 in turn using the above described apparatus. Again, the holder of the apparatus can be used to tilt the cuboid 100 during assembly so that the required face (i.e. the face to which the component is to be mounted) is held substantially horizontal during the process of dispensing the adhesive, attaching the component and curing the adhesive. A colloidal fluid comprising a suspension of metal ions in a dispersing medium may also be dispensed using the fluid dispenser along multiple paths between the components 102 and 104. The colloidal suspension can then be heated by the FAMOBS device to evaporate the dispersing medium of the colloid leaving the required pattern of metal tracks 106 deposited on the substrate and thereby electrically linking the components 102 and 104. In this manner, a circuit may be constructed on all or some of the faces of the cuboid and it would be recognised that such a technique could be used to attach components to any regular or irregular three-dimensional object. Such an object may have discrete faces and/or may comprise curved or bent surfaces.

Referring to FIG. 7, the steps of a method of using the apparatus described above with reference to FIGS. 1 and 2 is illustrated. In a first step 110 the substrate is placed in the required orientation by the holder 18. A second step 112 of dispensing an adhesive (e.g. a conductive adhesive) is performed. The second step 112 may involve dispensing such adhesive to one or more regions on the substrate. A third step 114 of placing one or more components in the adhesive is then carried out, before a fourth step 116 of curing the adhesive is performed. The second, third and fourth steps may involve moving the fluid dispensing device 12, the pick-up device 14 and the FAMOBS device 16 respectively by moving the moveable platform 8 and, optionally, the holder may be used to provide motion of the substrate during any or all of these steps. The whole process may then be repeated and, in particular, the first step 110 may involve re-orientating (tilting) the substrate to provide access to a further mounting face.

The methods outlined with reference to FIGS. 3 to 7 are described as being implemented using apparatus of the type illustrated in FIGS. 1 and 2. In other words, it is described in detail above how the various methods may be implemented using one piece of apparatus that carries a fluid dispenser, a component pick-up device and a FAMOBS device. It should, however, be noted that such methods could also be implemented using a series of single function machines. For example, a substrate could be passed from a first machine that carries a fluid dispenser to a second machine that carries a component pick-up device to a third machine that carries a FAMOBS device. In this manner, the fluid deposition, component placement and FAMOBS heating may be performed in series using different machines.

The above examples describe the deposition of a conductive adhesive onto a substrate. It should, however, be noted that any fluid or even a plurality of different fluids could be dispensed by the apparatus. For example, a solder paste could be dispensed that is activated (melted) by the FAMOBS device. The dispensed fluid also need not be used for attaching a component to the substrate. For example, an ink, a semiconductor material (e.g. an organic semiconductor) or a conductive material (e.g. in colloidal form) could be deposited. The deposited fluid could then perform some required function, such as form part of an electronic circuit. For example, conductive tracks could be laid on a substrate or semiconductor devices could be built on the substrate.

Furthermore, although the above apparatus includes a FAMOBS device, it should be noted that other types of activation device may be provided. For example, a UV curing source or a contact heater may be used. It is, however, preferable that the activation device provides controlled or localised action; e.g. that it can be directed to a specific region of fluid to overcome any unwanted effects associated with heating large areas of the substrate or exposing large areas of the substrate to radiation.

1. Apparatus for use in the manufacture of a non-planar circuit module, comprising;
a holder for holding a non-planar circuit module,
an activation source for activating one or more localised regions of a non-planar circuit module held by the holder, and
positioning apparatus for providing relative movement between the activation source and a non-planar circuit module held by the holder,
wherein the relative movement between the activation source and a non-planar circuit module held by the holder comprises translational movement along at least one axis and rotational movement about at least one axis.

2. An apparatus according to claim 1, wherein the positioning apparatus comprises a positioning device for moving the activation source, wherein the positioning device comprises a parallel positioning machine.

3. An apparatus according to claim 1, wherein the activation source comprises a heat source for heating one or more localised regions of a non-planar circuit module held by the holder.

4. An apparatus according to claim 1, wherein the activation source comprises a directional radiation source for directing radiation to one or more localised regions of a non-planar circuit module held by the holder.

5. An apparatus according to claim 4 wherein the directional radiation source comprises a frequency agile open ended microwave cavity.

6. An apparatus according to claim 1, wherein a non-planar circuit module held by the holder comprises a non-planar substrate, the non-planar substrate being held by the holder.

7. An apparatus according to claim 6 wherein the non-planar substrate held by the holder comprises two or more component mounting surfaces, wherein each of the two or more component mounting surfaces are located in different planes.

8. An apparatus according to claim 6, wherein the non-planar substrate comprises at least one curved component mounting surface.

9. An apparatus according to any claim 6, wherein a non-planar circuit module held by the holder further comprises a fluid deposited on the non-planar substrate, wherein the activation source can activate the deposited fluid.

10. An apparatus according to claim 9 in which the fluid comprises a solder paste and the activation source is arranged to melt the solder paste.

11. An apparatus according to any preceding claim 1, wherein the positioning apparatus comprises a positioning device that translates the activation source along a plurality of axes.

12. An apparatus according to claim 1, wherein the holder forms part of the positioning apparatus, wherein the holder comprises a tilting mechanism that enables a non-planar circuit module held by the holder to be tilted about at least one axis.

13. An apparatus according to claim 1, further comprising a fluid dispenser for dispensing fluid on to a non-planar circuit module held by the holder.

14. An apparatus according to claim 1, further comprising a component pick-up device for picking up components and placing such components on a non-planar circuit module held by the holder.

15. An apparatus according to claim 1, wherein the activation source is releasably attachable to the positioning apparatus.

16. Apparatus for use in the manufacture of a circuit module, comprising;
a holder for holding a circuit module,
a heat source for heating one or more localised regions of material on the circuit module, and
positioning apparatus for providing relative movement between the heat source and a circuit module held by the holder,
wherein the relative movement between the heat source and a circuit module held by the holder comprises translational movement along at least one axis and rotational movement about at least one axis.

17. A method of manufacturing a non-planar circuit module, the method comprising the steps of;
(i) taking a non-planar circuit module; and
(ii) bringing an activation source in to an operative position relative to the non-planar circuit module and using the activation source to activate one or more localised regions of the non-planar circuit module,
wherein step (ii) comprises the step of using positioning apparatus to move the activation source relative to the non-planar circuit module, wherein the relative movement between the activation source and a non-planar circuit module held by the holder comprises translational movement along at least one axis and rotational movement about at least one axis.

18. A method according to claim 17 wherein step (ii) comprises the step of moving the activation source and the step of tilting the non-planar circuit module.

19. A method according to claim 17, wherein step (i) comprises the step of taking a non-planar circuit module comprising a non-planar substrate having a fluid deposited thereon.

20. A method according to claim 19 wherein the fluid deposited on the non-planar substrate comprises solder paste.

21. A method according to claim 20 wherein step (ii) comprises using the activation source to melt the solder paste.

22. A method according to claim 17, wherein step (i) comprises the step of taking a non-planar circuit module comprising a substrate having at least one electrical component located thereon.

23. A method according to claim 17, wherein the activation source used in step (ii) comprises a microwave radiation source.
